(19) United States
(12) Patent Application Publication
(10) Pub. No.: US 2005/0067650 A1
(43) Pub. Date: Mar. 31, 2005

(54) Component having an adjustable thin-film capacitor

(75) Inventors: Frank Schnell, Gerlingen (DE); Ralf Schmidt, Gerlingen (DE)

Correspondence Address: KENYON & KENYON, ONE BROADWAY, NEW YORK, NY, 10004, US

(73) Assignee: Robert Bosch GmbH

(21) Appl. No.: 10/922,401

(22) Filed: Aug. 19, 2004

(30) Foreign Application Priority Data
Sep. 25, 2003 (DE) 103 44 616.8

(51) Int. Cl. H01L 27/108

(52) U.S. Cl. 257/307

(57) ABSTRACT

A component having at least one adjustable thin-film capacitor is described, which may be manufactured particularly cost-effectively because of its simple design. The component structure is implemented on a substrate and includes at least one first electrically conductive layer and a second electrically conductive layer, which are separated from one another by at least one ferroelectric interlayer. At least one first electrode of the thin-film capacitor is implemented in the first electrically conductive layer, while at least a second electrode of the thin-film capacitor is implemented in the second electrically conductive layer. The capacitor area of the thin-film capacitor is defined exclusively by the overlap region of the first and the second electrodes.

### FIELD OF THE INVENTION

The present invention relates to a component having at least one adjustable thin-film capacitor. The component structure is implemented on a substrate and includes at least one first electrically conductive layer and a second electrically conductive layer, which are separated from one another by at least one ferroelectric interlayer. At least one first electrode of the thin-film capacitor is implemented in the first electrically conductive layer and at least one second electrode of the thin-film capacitor is implemented in the second electrically conductive layer.

Furthermore, the present invention relates to a component having at least one phase modifier, for electronic alignment of the emission direction of a patch antenna in particular, the phase modifier including a thin-film capacitor which is implemented as described above.

### BACKGROUND INFORMATION

In the article entitled “Microwave Integrated Circuits using Thin-Film BST” by R. York, A. Nagra, E. Erker, T. Taylor, P. Periaswamy, J. Speck, S. Streiffer, D. Kaufmann, and O. Auciello, which appeared in ISAF Conference Honolulu Hawaii, Jul. 21-Aug. 2, 2000, a method is described for manufacturing a component of the type described above, i.e., an adjustable thin-film capacitor of this type. In this case, the substrate is first provided with a platinum layer, over which a barium-strontium-titanate (BST) layer is then produced as the ferroelectric interlayer. Subsequently, the BST layer and then the platinum layer are structured, so that an electrode region coated with BST, which is separated from the remaining platinum layer, results. An insulation layer made of silicon nitride is then deposited over this electrode region and structured. At the same time, openings are produced in the electrode region which finally determine the capacitor area. Finally, a further platinum layer is deposited over the insulation layer structured in this way.

The structure of an adjustable thin-film capacitor described in this article has four-layers and includes a metallic base electrode directly on the substrate, a ferroelectric interlayer, a structured insulation layer, and a final metal electrode, which completes the capacitor. The insulation layer having the openings through which the capacitor area is determined is used for the purpose of compensating for calibration errors during the processing and structuring of the thin-film capacitor, in order to maintain a predetermined nominal capacitance.

The emission direction of a patch antenna is determined by the phase relationship between the individual patches, which is typically fixed and results from the design of the patch supply leads in relation to one another. Through controllable phase modifiers, which are integrated into the supply lead paths of the individual patches, the phase angle of the patches in relation to one another may be influenced in a targeted way and therefore the emission direction of the patch antenna may also be changed in a targeted way.

Using electronically controllable ferroelectric phase modifiers, in which the dependence of the permittivity of a ferroelectric layer on the applied electric field is exploited, to implement a targeted phase shift of this type is conventional. The propagation speed of the HF signal and therefore the phase angle at the component output changes due to the permittivity, which is changed in proximity to the lead.

Ferroelectric phase modifiers may be implemented simply in the form of a coplanar lead part which runs on a substrate provided with a ferroelectric layer. The ferroelectric layer is typically an undoped or doped barium-strontium-titanate layer in various compositions of 0.1 μm to 0.5 μm thickness. The electric field for tuning the permittivity of the ferroelectric layer is applied here via the gap between the signal lead and the grounded area of the coplanar lead. Since the necessary electrical fields may only be achieved using relatively high DC voltages in the lateral direction in the range from a few tens to one hundred volts because of the lead geometry and the width of the gap in particular, a split phase modifier design is suggested which allows tuning of the permittivity of the ferroelectric layer using lower DC voltages. In this case as well, the phase modifier is implemented in the form of a coplanar lead part. However, transverse webs, which originate from the signal lead and also from the grounded area, project into the relatively wide gap here. These transverse webs form one electrode side of adjustable thin-film capacitors which are positioned in the proximity of the grounded area. The other electrode side is formed in each case by an electrode which is positioned in the region below the transverse webs and is separated from the transverse webs by a ferroelectric interlayer. The voltage is applied across the layer thickness in this case and is a few volts.

As already noted, the permittivity of the ferroelectric layer is influenced by applying a DC voltage between the grounded area and signal lead. This DC voltage must be separated from the HF voltage, which powers the patch antenna. In the literature—L. Sengupta: “Bulk Ceramic Ferroelectrics and Composites: Manufacture, Microwave Properties, and Applications”, Workshop on Ferroelectric Materials and Microwave Applications at the 2000 IEEE MTT-S International Microwave Symposium, Boston (MA) 2000—it was suggested that the grounded areas be divided in two over the length of the phase modifier and separated from one another by a narrow gap. The DC signal is applied here at the part of the grounded area facing toward the signal lead, while the HF signal is applied to the external part. This has the result that the HF part of the grounded area must be bridged by the DC supply lead in an insulated way. For this purpose, at least one additional insulation layer and one additional electrically conductive layer are necessary, which complicates the overall implementation of the component.

### SUMMARY

In accordance with an example embodiment of present invention, a component is provided having at least one adjustable thin-film capacitor of the type initially cited which may be manufactured particularly cost-effectively because of its simple design.

This may achieved according to the present invention in that the capacitor area of the thin-film capacitor is exclusively defined by the overlap region of the first and the second electrodes.

It has been recognized, according to the present invention, that the capacitor area of a thin-film capacitor does not necessarily have to be defined with the aid of an appropriately structured additional interlayer, but rather may also be determined simply by the overlap region of the first and the second electrodes, i.e., by the geometry and the arrangement of the electrodes in relation to one another. In this way, a thin-film capacitor having a layer structure which includes only three layers may be implemented, which significantly reduces the manufacturing outlay.

In principle, there are different possibilities for implementing the component according to the present invention and for the design of the thin-film capacitor in particular. Since the capacitor area is determined according to the present invention solely by the geometry of the two electrodes and their positioning in relation to one another, a design may be implemented through suitable selection of the electrode size and shape, using which a predetermined nominal capacitance and/or the capacitor area may be maintained exactly, but which is nonetheless especially unsusceptible to calibration errors, in particular to shifts of the individual layers of the layer structure in the x/y direction. In a preferred embodiment of the component according to the present invention, the first and the second electrodes are implemented for this purpose in the form of lead sections of predetermined width, which intersect at a predetermined angle. It is particularly advantageous in this context if the size and/or the length of the first and the second electrodes, as well as the lateral extension of the ferroelectric region between the first and the second electrodes, are selected as a function of the calibration precision to be expected during the processing of the first and the second electrically conductive layers and the ferroelectric interlayer.

As described above, a conventional design for split phase modifiers, which may be used for the electronic alignment of the emission direction of a patch antenna, for example, includes adjustable thin-film capacitors. The design according to the present invention may be advantageous for this purpose, since it permits the manufacture of split phase modifiers having a three-layer layer structure. In a preferred embodiment, the component structure is implemented on a substrate and includes at least one first electrically conductive layer, in which at least one signal lead and at least one grounded area are implemented coplanarly and are separated from one another by a gap of defined width. At least one transverse web, which projects into the gap, originates from the signal lead and at least one transverse web, which projects into the gap, also originates from the grounded area, so that the transverse webs form at least one coplanar capacitor. At least one electrode, which is separated by at least one ferroelectric interlayer from the transverse webs forming the coplanar capacitor and which forms an adjustable thin film capacitor with at least one of the transverse webs, is implemented in a further layer in the region of the coplanar capacitor. The capacitor area of the thin-film capacitor is defined exclusively by the overlap region of the electrode and the transverse web. Means, e.g., an arrangement for applying an adjustable DC voltage are also provided between the signal lead and the grounded area in the region of the transverse webs. In consideration of a design which is as tolerant of calibration errors as possible, it has been shown to be advantageous if the electrodes and the at least one transverse web are implemented in the form of lead sections of a predetermined width, which intersect at a predetermined angle.

In a particularly advantageous variation of a component having a split phase modifier, the DC voltage signal applied to the grounded area is decoupled from the HF signal applied to the grounded area with the aid of interdigital capacitors which separate the region of the grounded area in which transverse webs are implemented from the remaining grounded area. The geometry of the interdigital capacitors, in particular the width of the gap, the number and the length of the fingers, and the overlap, may be tailored to the operating frequency of the component. Since the structure for decoupling the DC signal and HF signals does not extend over the entire length of the component, the parts of the phase modifier which are to have the DC voltage applied to them may be accessed easily from the outside for contact.

Decoupling of the DC voltage signal applied to the grounded area from the HF signal applied to the grounded area may alternatively also be implemented if the metal platings for the DC voltage signal and for the HF signal run in different layers which are separated from one another by a non-conductive layer. In this case, the ferroelectric interlayer may advantageously be used as the non-conductive layer between the metal platings for the DC signal and HF signal. Through suitable selection of the geometry in the size, overlap, and layer thickness, the properties of the phase modifier may be influenced in a targeted way.

In principle, there are different possibilities for the wiring of the phase modifier described above. In one variation, which is particularly simple to implement via the remaining circuit, the signal lead is grounded in relation to the DC voltage supply of the BST capacitors, while the decoupled grounded areas are wired homopolar or heteropolar. However, a heteropolar wiring of the grounded areas is also possible, the signal lead also being grounded in relation to the DC voltage.

For special cases, it may be necessary to decouple the signal lead itself, which may be performed via interdigital capacitors or through an insulated overlap of the metal plating layers at the beginning and end of the signal lead, similarly to the decoupling of the grounded areas. In these cases, the DC wiring is heteropolar, using +5V at one grounded area and −5V at the other grounded area, for example. The potential on the signal lead then results from the DC wiring of the grounded areas and is not uniquely determined. An additional DC contact of the signal lead, which may be produced via bonded wires or even an additional supply lead insulated from the remaining structure, would be necessary to uniquely determine the potential of the signal lead.

### BRIEF DESCRIPTION OF THE DRAWINGS

As already extensively explained above, there are different possibilities for advantageously implementing and refining the teaching of the present invention. Reference is made to the following description of multiple exemplary embodiments of the present invention and to the figures.

FIG. 1 shows a design of a split phase modifier having thin-film capacitors and decoupling of the grounded areas via interdigital capacitors.

FIG. 2 shows a detail illustration of the structure of a thin-film capacitor of the phase modifier shown in FIG. 1.

FIG. 3 illustrates the insensitivity of the design shown in FIG. 2 to the precision of the adjustment of the individual layers of the layer structure in relation to one another.

FIG. 4 shows six different variants of thin-film capacitors.

FIG. 5 shows two different design variants for interdigital capacitors for decoupling the DC signal and HF signal in the grounded areas.

FIG. 6 shows four different wiring examples for the phase modifier.

### DETAILED DESCRIPTION OF EXAMPLE EMBODIMENTS

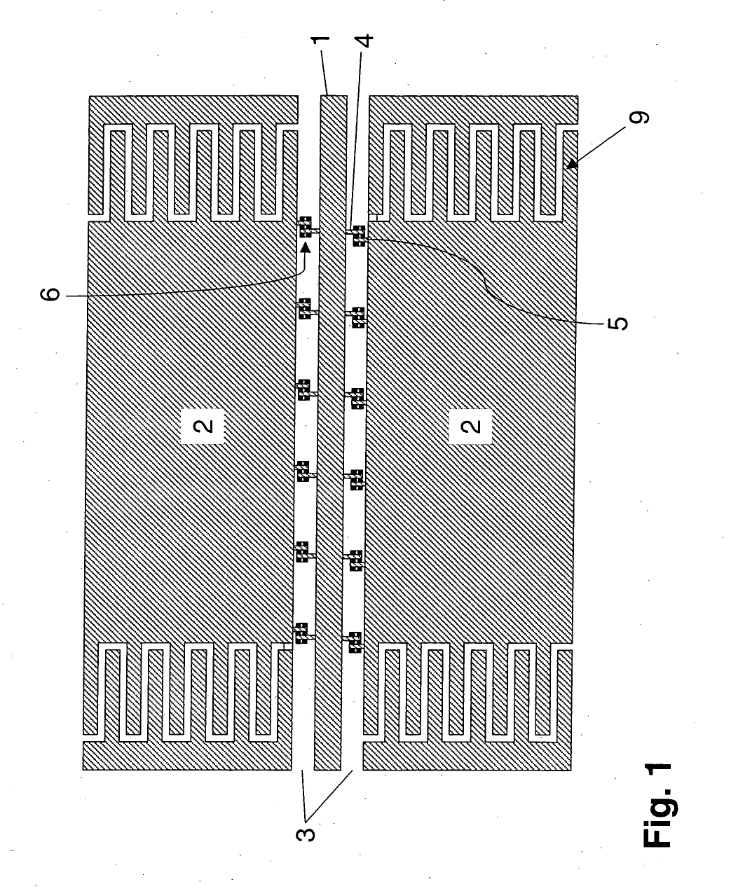

FIG. 1 shows the top view of a phase modifier, which may be used for the electronic alignment of the emission direction of a patch antenna, for example.

The component structure is implemented on a substrate and includes a first electrically conductive layer, in which a signal lead 1 and two grounded areas 2 are implemented. Signal lead 1 runs coplanarly between the two grounded areas 2 and is separated from each of them by a gap 3 of a defined width. On both sides, transverse webs 4, which project into particular gap 3, originate from signal lead 1. In addition, transverse webs 5, which originate from grounded areas 2, project into both gaps 3. Transverse webs 4 and 5 are positioned in such a way that they form coplanar capacitors 6 near grounded areas 2.

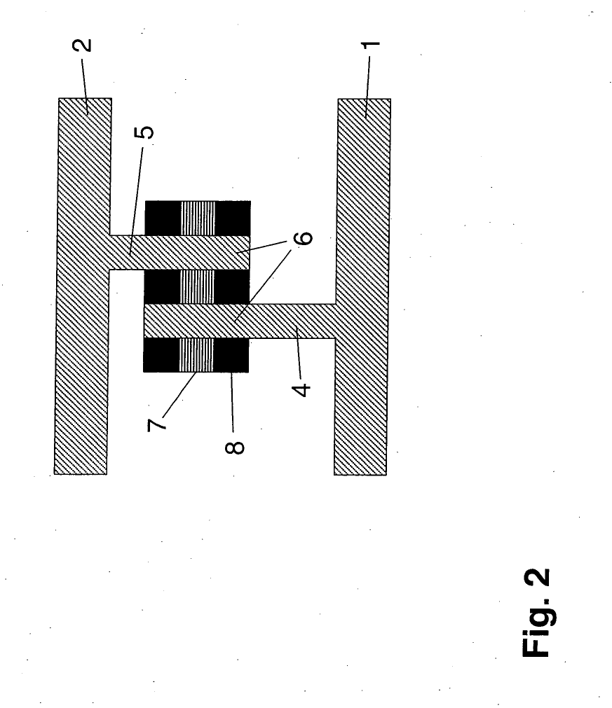

A further electrically conductive layer is positioned between the substrate and the first electrically conductive layer, in which electrodes 7 are implemented in the region of coplanar capacitors 6, which are separated by at least one ferroelectric interlayer 8 from transverse webs 4 and 5 forming coplanar capacitors 6. These electrodes 7 and each of transverse webs 4 and 5 form a coplanar capacitor 6 of an adjustable thin-film capacitor, as is shown in FIG. 2. According to the present invention, the capacitor area of such an adjustable thin-film capacitor is defined exclusively by the overlap region of electrodes 7 and particular transverse webs 4 and 5.

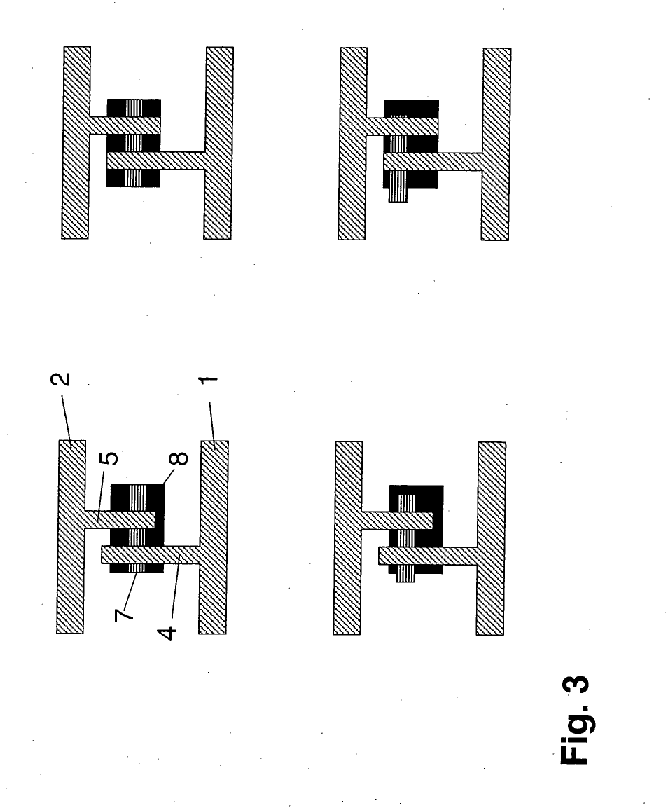

In the exemplary embodiments shown here, electrodes 7 and transverse webs 4 and 5 are implemented in the form of lead sections of a predetermined width and intersect generally at a right angle. Both the size of the overlap and the lateral extension of ferroelectric interlayer 8, which simultaneously functions as the insulation layer between the two electrode sides of the thin-film capacitor, conform to the tolerances to be expected from the adjustment precision of the three layers—first electrically conductive layer, ferroelectric interlayer 8, and further electrically conductive layer—to one another, which is illustrated by FIG. 3. It is to be noted here that with the aid of the design according to the present invention, adjustment precisions which result from x/y displacements of the three layers in relation to one another may be tolerated. Furthermore, twisting of the three layers in relation to one another influences the nominal value of the thin-film capacitor and also the size of the parasitic capacitances. The errors caused by twisting may, however, be kept at a tolerably low scope by calibration marks on the etching mask which are relatively widely separated from one another. Parasitic capacitances which arise at the edges of the electrodes remain uninfluenced by a displacement of the layers toward one another and may therefore be taken into consideration in the design geometry.

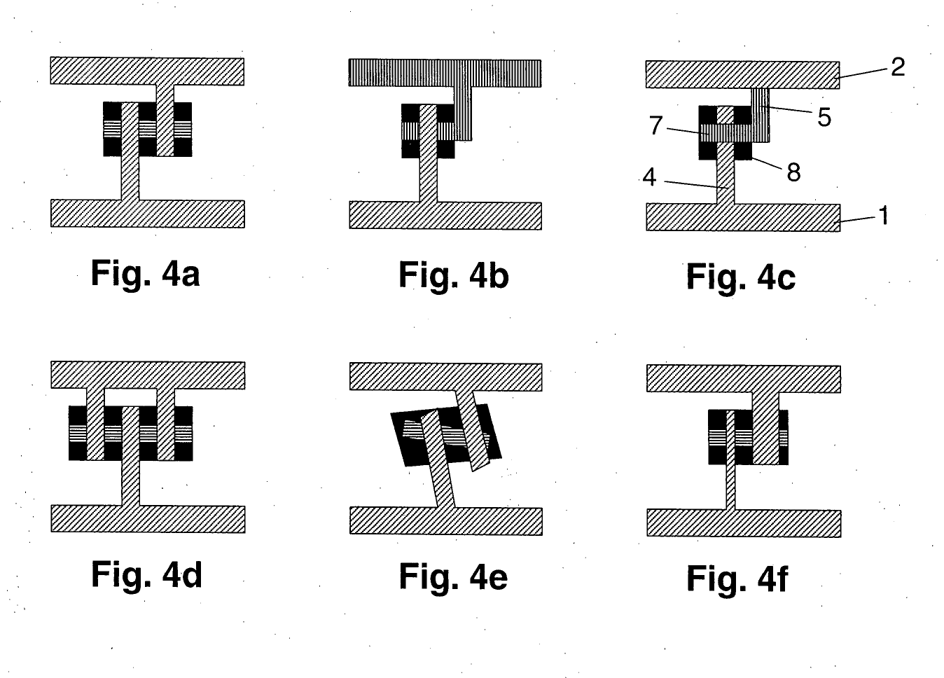

The exemplary embodiments for adjustable thin-film capacitors shown in FIGS. 4a through 4f are all structured in three layers and are based on the principle of overlapping electrodes which are separated from one another by a ferroelectric insulation layer, i.e., interlayer. The variant shown in FIG. 4a corresponds to the illustration in FIG. 2 and represents a series circuit of two capacitors and correspondingly a reduction of the nominal value of the thin-film capacitor. FIG. 4b shows a two-layer structuring of the HF structure. In the variant shown in FIG. 4c, upper electrode 5 and lower electrode 7 are in contact. FIG. 4d shows a thin-film capacitor having a symmetrical structure. In the variants shown in FIG. 4e, lower electrode 7 and upper electrodes 4 and 5 intersect in an angle other than a right angle. FIG. 4f shows a variant in which both upper electrodes 4 and 5 of the thin-film capacitor are implemented in different widths.

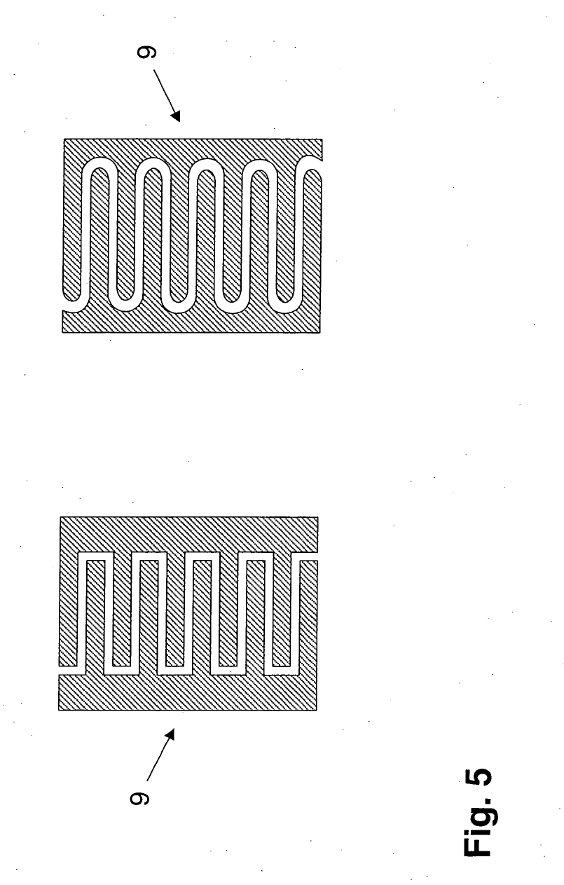

An adjustable DC voltage must be applied between signal lead 1 and grounded areas 2 in the region of transverse webs 4 and 5 to regulate the thin-film capacitors of the phase modifier shown in FIG. 1. The DC and HF signals of grounded areas 2 are decoupled by interdigital capacitors 5, whose geometry, in particular the width of the gap, the number and length of the fingers, and the overlap, may be tailored to the operating frequency of the component. Two variants of an interdigital capacitor 9 of this type are shown in FIG. 5, a first one having angular geometry and a second one having rounded geometry. Since these interdigital capacitors 9 do not extend over the entire length of the component, the parts of the phase modifier which are to have a DC voltage applied to them may be contacted easily from the outside.

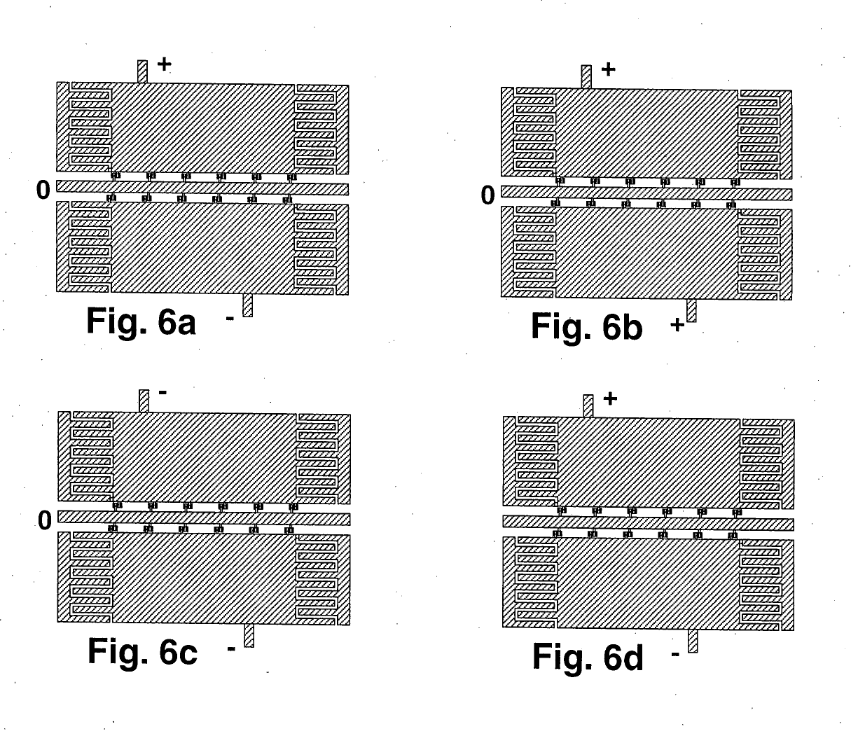

Four different possibilities for the wiring of the phase modifier shown in FIG. 1 are shown in FIGS. 6a through 6d. In the variants shown in FIGS. 6a through 6c, signal lead 1 is grounded, which may be implemented very easily via the remaining circuit. In FIG. 6a, grounded areas 2 are wired heteropolar, while grounded areas 2 in FIGS. 6b and 6c are jointly at positive and negative voltage, respectively. FIG. 6d shows a wiring variant in which signal lead 1 is also decoupled and the DC wiring of grounded areas 2 is heteropolar, using +5V on one grounded area 2 and −5V on the other grounded area 2, for example. The potential of signal lead 1 then results from the DC wiring of grounded areas 2 and is not uniquely determined. For this purpose, additional DC contacting of signal lead 1 would be necessary, which may be performed via bonded wires or even an additional supply lead insulated from the remaining structure, for example.

1. A component having at least one adjustable thin-film capacitor, and implemented on a substrate, the component comprising:
a first electrically conductive layer and a second electrically conductive layer, which are separated from one another by at least one ferroelectric interlayer, at least one first electrode of the thin-film capacitor being implemented in the first electrically conductive layer and at least a second electrode of the thin-film capacitor being implemented in the second electrically conductive layer;
wherein a capacitor area of the thin-film capacitor is defined exclusively by an overlap region of the first electrode and the second electrode.

2. The component as recited in claim 1, wherein the first electrode and the second electrode are implemented in the form of lead sections of predetermined width, which intersect at a predetermined angle.

3. The component as recited in claim 1, wherein at least one of a size and a length of the first electrode and the second electrode, and a lateral extension of a ferroelectric interlayer including a ferroelectric region between the first electrode and the second electrode, are selected as a function of an adjustment precision to be expected during processing of the first and the second electrically conductive layers and the ferroelectric interlayer.

4. A component implemented on a substrate and having at least one phase modifier for electronic alignment of an emission direction of a patch antenna, comprising:
at least one first electrically conductive layer;
at least one signal lead and at least one grounded area coplanar in the first electrically conductive layer and separated from one another by a gap of a defined width;
at least one first transverse web which projects into the gap and originate, from the signal lead;
at least one second transverse web which projects into the gap and originates from the grounded area, the first and second transverse webs together forming at least one capacitor;
at least one electrode which is separated from the first and second transverse webs by at least one ferroelectric interlayer and forms an adjustable thin-film capacitor together with at least one of the first and second transverse webs, the electrode being implemented in a further layer in a region of the capacitor, wherein a capacitor area of the capacitor is defined exclusively by an overlap region of the electrode and the first and second transverse webs; and
an arrangement configured to apply an adjustable DC voltage signal between the signal lead and the grounded area in a region of the first and second transverse webs.

5. The component as recited in claim 4, wherein the electrode and the at least one of the first and second transverse web are implemented in a form of lead sections of a predetermined width, which intersect at a predetermined angle.

6. The component as recited in claim 4, wherein the DC voltage signal applied to the grounded area is decoupled from an HF signal applied to the grounded area via interdigital capacitors which separate a region of the grounded area in which the second transverse web is implemented, from the remaining grounded area.

7. The component as recited in claim 6, wherein a geometry of the interdigital capacitors is adapted to an operating frequency of the component.

8. The component as recited in claim 7, wherein a width of the gap, and a number and a length of fingers of the interdigital capacitors are adapted to the operating frequency of the component.

9. The component as recited in claim 6 further comprising:
metal platings for the DC voltage signal and for the HF signal run in different layers, the different layers being separated from one another by a non-conductive layer.

10. The component as recited in claim 9, wherein the ferroelectric interlayer is used as the non-conductive layer between the metal platings for the DC voltage signal and the HF signal.

11. The component as recited claim 4, wherein the signal lead is grounded, and the grounded area is wired in a homopolar or heteropolar manner.

12. The component as recited in claim 4, wherein the signal lead is decoupled, the grounded area is wired in a heteropolar manner, and a DC voltage contact of the signal lead is provided.
